(19) United States
(12) Patent Application Publication
(10) Pub. No.: US 2003/0116776 A1
(43) Pub. Date: Jun. 26, 2003

(54) Substrate stack

(76) Inventor: Hermann Oppermann, Berlin (DE)

Correspondence Address: GARDNER GROFF, P.C., PAPER MILL VILLAGE, BUILDING 23, 600 VILLAGE TRACE, SUITE 300, MARIETTA, GA, 30067, US

(21) Appl. No.: 10/287,945

(22) Filed: Nov. 5, 2002

(30) Foreign Application Priority Data
Nov. 12, 2001 (DE) 101 55 417.6
Apr. 25, 2002 (DE) 102 24 371.9

(51) Int. Cl. H01L 33/00

(52) U.S. Cl. 257/100

(57) ABSTRACT

A substrate stack includes a first substrate, a second substrate arranged opposite the first substrate, a frame connecting the first substrate and the second substrate to each other and a core element also connecting the first substrate and the second substrate to each other and arranged within the frame, wherein the frame is a closed frame or comprises one or several openings, wherein the one or several openings occupy less than half of the perimeter of the frame.

### BACKGROUND OF THE INVENTION

1. Field of the Invention

The present invention relates to a compound device, wherein two substrates arranged in parallel are connected, and in particular to such a compound device which includes a high-frequency signal line between the substrates.

2. Description of the Related Art

Two substrates, for example a conductor plate and a chip carrier are conventionally connected using a BGA (BGA=Ball Grid Array) in an electrically conductive way. In order to compensate for differences in height and deviations of the opposing surfaces of the two substrates from a perfect parallelism and to guarantee a good reliability, the solder balls of the BGA are as high as possible having a diameter of approximately 300 μm to 450 μm. In the case of a ceramic chip carrier and a conductor plate, high-leaded solder balls having a diameter of typically 700 μm to 800 μm or even 2,000 μm long solder columns are used in order to reduce mechanical tensions occurring due to the different coefficients of thermal expansion of the ceramic chip carrier and the conductor plate.

For high-frequency applications a BGA is usually constructed so that a contact for the signal line is surrounded by a plurality of ground contacts. The individual contact elements are at that time equal to each other and are formed from the solder balls. If pins are used instead of the solder balls this is referred as a PGA (PGA=Pin Grid Array).

For reducing or accepting, respectively, the mechanical tensions, the gap between the two substrates is filled completely or partially with a polymer material. The polymer material needs to meet certain requirements regarding its coefficient of thermal expansion and its modulus of elasticity. In this regard, the best results were achieved using epoxy resins with ceramic fillers. Filled epoxy resins are, however, not suitable for high-frequency applications due to their dielectric properties and their attenuation losses.

### SUMMARY OF THE INVENTION

It is the object of the present invention to provide an improved substrate stack suitable for high-frequency applications and a method for producing the same and a substrate and an auxiliary substrate for being used in the manufacturing process.

In accordance with the present invention, a substrate stack comprises a first substrate, a second substrate arranged opposite the first substrate, and a frame connecting the first substrate and the second substrate to each other. The frame is a closed frame or comprises one or several openings, which occupy less than half of the perimeter of the frame. Further, the substrate stack comprises a core element, also connecting the first substrate and the second substrate to each other and arranged within the frame.

In accordance with the present invention, a method for producing a substrate stack, comprises providing a first substrate, providing a second substrate and depositing a frame onto the first substrate, wherein the frame is a closed frame or comprises one or several openings, wherein the one or several openings occupy less than half of the perimeter of the frame. Further the method comprises depositing the core element onto the first substrate or onto the second substrate and depositing the frame onto the second substrate in order to connect the first substrate and the second substrate to each other, wherein the core element is arranged in the interior of the frame.

In accordance with the present invention, a substrate, comprises a frame which is attached on the substrate and is closed or comprises one or several openings. The one or several openings occupy less than half of the perimeter of the frame. Further, the substrate comprises a core element arranged on the substrate within the frame. The frame and the core element are provided for connecting the substrate to a further substrate.

In accordance with the present invention, an auxiliary substrate, comprises a frame which is arranged on the auxiliary substrate and which is closed or comprises one or several openings. The one or several openings occupy less than half of the perimeter of the frame. Further, the auxiliary substrate comprises a core element which is arranged on the auxiliary substrate within the frame. The frame and the core element are provided to be transmitted to a first substrate from the auxiliary substrate in order to connect the first substrate to a second substrate.

The present invention is based on the findings that two substrates are connected through a frame and a core element arranged within the frame.

It is an advantage of the present invention that the frame provides a stable mechanical connection between the two substrates.

According to a preferred embodiment the frame and the core element are electrically conductive, wherein the core element provides an electrically conductive connection for transmitting signals between the substrates and wherein the frame causes an electromagnetic shielding of the core element which is why it is preferably grounded.

It is a special advantage of this embodiment that the frame forms a complete shielding of the core element and the signals transferred via the core element, respectively, against external electromagnetic influences.

According to a further preferred embodiment a gap between the substrates outside the frame is filled by a cast compound or an underfiller, respectively, preferably by a filled epoxy resin in a fluid state. The compound forms a connecting body after hardening providing a further mechanical connection between the substrates. In this respect, a further advantage of the present invention is that the frame prevents the fluid cast compound from penetrating the gap between the core element and the frame. Thereby, an interference of the signal path between the substrates formed by the core element and the frame due to possible inadequate dielectric properties or attenuation losses in the compounds is prevented and excellent electrical properties are guaranteed also in the high-frequency range.

One preferred application of the present invention is with a stack of substrates comprising different materials with different coefficients of thermal expansion, for example a conductive trace of organical material and a ceramic chip carrier. In such cases the different coefficients of thermal expansion may lead to great mechanical stresses of the connection between the substrates. According to the latter embodiment these mechanical stresses are taken up by the connecting body, whereby the frame and the core element are mechanically relieved. The reliability of the electrical connection formed by the core element and the frame between the substrates is strongly improved by this. Simultaneously, the connecting height, i.e. the distance between the two substrates, may be strongly reduced to 50 μm to 200 μm or even to smaller values, as the connecting body keeps away thermomechanical stresses from the core element and the frame to a large extend. These short connecting heights are especially advantageous and desired regarding a low-reflection signal transmission.

The present invention thus facilitates an improved mechanical stability and thereby an improved reliability of a substrate stack and simultaneously an improvement of the high-frequency properties in a unique way. The latter results both from the reduced connecting height and from the absence of the cast compound and the connecting body, respectively, between the core element and the frame.

These and other objects and features of the present invention will become clear from the following description taken in conjunction with the accompanying drawing, in which:

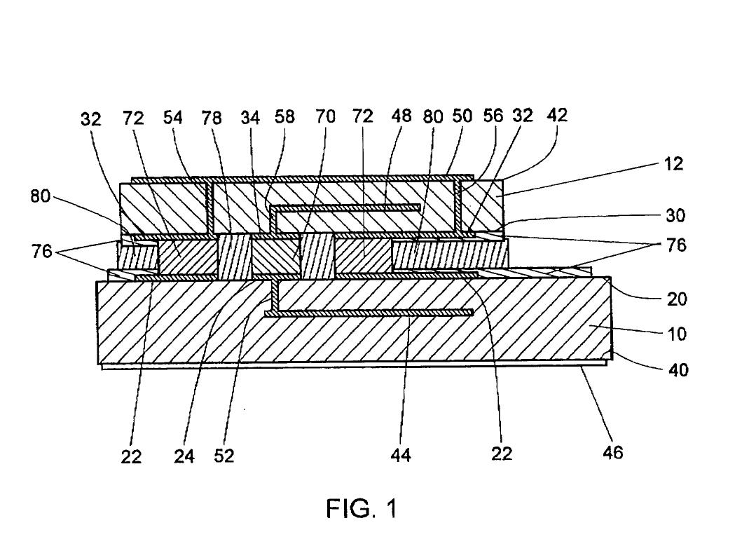

FIG. 1 is a schematical sectional illustration of a substrate stack according to a first embodiment of the present invention;

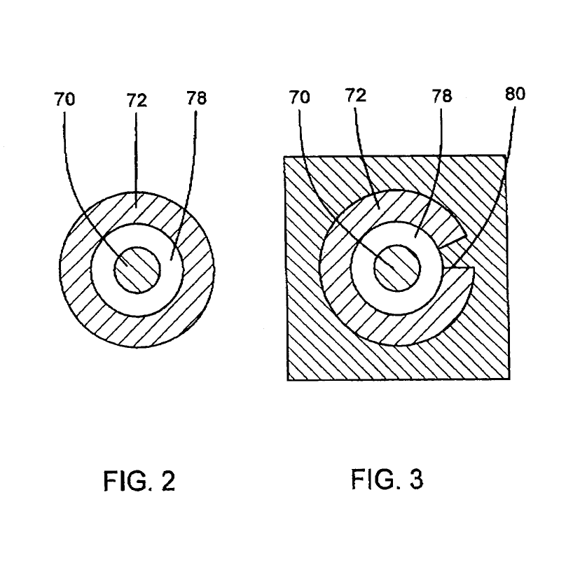

FIG. 2 is a schematical illustration of a frame and a core element according to the embodiment illustrated in FIG. 1; and

FIG. 3 is a schematical sectional view of a further embodiment of the present invention.

### DESCRIPTION OF THE PREFERRED EMBODIMENTS

FIG. 1 is a schematical illustration of a section through a substrate stack according to a first embodiment of the present invention, wherein the section is arranged perpendicular to a first substrate 10 and a second substrate 12 and parallel to the stacking direction of the substrates, respectively. The first substrate 10 is, for example, a multi-layer conductor plate and comprises a first conductive trace 22 and a second conductive trace 24 on a first surface 20. The second substrate 12 is, for example, a ceramic chip carrier of LTCC (LTCC=Low Temperate Cofired Ceramic) comprising an especially low coefficient of thermal expansion, or of a different ceramic material. It comprises a third conductive trace 32 and a fourth conductive trace 34 on a first surface 30. Further, the substrates 10, 12 comprise one or several further conductive traces 44, 46, 48, 50 each on their surfaces 40, 42 and/or within their interior, which are connected to each other through via holes or through holes 52, 54, 56, 58, respectively, and/or to the first, second, third and fourth conductive traces 22, 24, 32, 34 in an electrical conductive way.

Preferably, the first conductive trace 22 and a further conductive trace 46 are grounded, wherein the through hole conductor 52 is shielded between the first conductive trace 32 and the further conductive trace 46 against exterior electromagnetic fields through the same and through a circular arrangement of through hole conductors, which are not illustrated. Accordingly, preferably the third conductive trace 32 and the further conductive trace 50 are grounded, wherein the through hole conductor 58 is shielded between the third conductive trace 32 and the further conductive trace 50 against exterior electromagnetic fields through the same and through a circular arrangement of through hole conductors, which are not illustrated.

The first surface 20 of the first substrate 10 and the first substrate 30 of the second substrate 12 are arranged opposingly and preferably substantially parallel to each other. The second conductive trace 24 and the fourth conductive trace 34 are preferably arranged mirrored and opposite each other and connected to each other through a core element 70 in a mechanically and electrically conductive way. The first conductive trace 22 and the third conductive trace 32 are at least partially arranged opposite each other and connected to each other through a circular frame 72 in a mechanically and electrically conductive way. The areas of the first conductive trace 22 and the third conductive trace 32 which are not abutting the frame 72 are covered with solder stop layers 76. The frame 72 encloses the core element 70 completely or at least partially in a lateral direction as it is discussed in more detail below referring to the FIG. 2 and 3.

A gap 78 between the core element 70, the second conductive trace 24 and the fourth conductive trace 34 on the one hand and the frame 72, the first conductive trace 22 and the third conductive trace 32 on the other hand is preferably filled with air or a different gas and electrically insulates the core element 70 and the frame 72 from each other. Outside the frame 72 a connecting body 80 is arranged between the first substrate 10 and the second substrate 12 and between the solder stop layers 76, respectively, which combines the same mechanically.

The core element 70 and the frame 72 together form a substantially coaxial arrangement for an electromagnetically shielded transmission of electrical signals between the substrates 10, 12. An electrical signal is thereby transmitted via the through hole conductor 52, the second conductive trace 24, the core element 70, the fourth conductive trace 34 and the through hole conductor 58 from a conductive trace 44 in the first substrate 10 to a conductive trace 48 in the second substrate 12, or vice versa. The frame 72 together with the first conductive trace 22 and the third conductive trace 32 forms an electromagnetic shielding for this signal path and is therefore connected to a further conductive trace 50 over the through hole conductors 54, 56 which forms a shielding for the signal path in the second substrate 12. Preferably, the exterior dimensions of the core element 70 and the interior dimensions of the frame 72 and the dimensions of the gap 78, respectively, are selected so that the signal path between the substrates 10, 12 comprises a desired impedance and a desired wave resistance, respectively, for example 50Ω.

FIG. 2 is a schematical illustration of a section parallel to the surfaces 20, 30, 40, 42 of the substrates 10, 12 through the core element 70 and the frame 72. The connecting body 80 is not illustrated. The frame 72 has the shape of an annular ring and is arranged coaxially to the core element 70. Interior diameters of the frame 72 and exterior diameters of the core element 70 determine the impedance of the signal path.

FIG. 3 is a schematical illustration of a section through a substrate stack according to a further preferred embodiment of the present invention, wherein the Section is again arranged in parallel to the surfaces of the substrates and between the same. In contrast to FIG. 2 the connecting body 80 is also illustrated. The embodiment illustrated in FIG. 3 is only different from the one illustrated in FIGS. 1 and 2 in so far that the frame 72 comprises an opening 82. The opening 82 is provided in order to lead away liquid or also gaseous substances (for example flux components during soldering) within the gap 78 during the manufacturing process. The connecting body 80 abuts to the frame 12 on the outside and surrounds the same completely. It further reaches into the opening 82, not however into the gap 78 between the frame 72 and the core element 70.

The core element 70 and the frame 72 are preferably formed from a solder, for example from SnPb, SnAg, SnCu. The manufacturing of the substrate stack includes a simple soldering process in this case. The solder is cost-effectively used up by applying a solder paste using a template or a screen printing technology. Also advantageous is the use of preforms or solder balls, which is especially obvious for forming the core element 70. If the frame 72 is formed from solder, a formation of one or several openings 82 in the frame 72 is simply realizable by the fact that the metallization to which the solder is applied, i.e. the first conductive trace 22 and/or the second conductive trace 32 is interrupted at the corresponding locations, as most substrate materials are not wetted by a solder. The same effect is obtainable if one or both of the solder stop layers 76 are constructed tongue-shaped, the tongue extending into the interior up to the gap 78, as also a solder stop layer is not wetted by a solder.

During manufacturing the inventive substrate stack first of all the solder paste is applied in the shape of the frame and the core element to the substrate 10, or the first conductive trace 22 and the second conductive trace 24, and/or to the substrate 12, or the third conductive trace 32 and the fourth conductive trace 34. The solder paste is then remelted by heating it to a temperature above its melting temperature, wherein the solder wets all areas of the metallization and the conductive traces 22, 24, 32, 34, respectively, which are not covered by the solder stop layer 76. The solder stop layer 76 thus determines the exterior shape of the frame 72, and, if it is also provided in the area of the gap 78, also the shape of the core element 70 and of the interior edge of the frame 72.

The flux freed during remelting is consequently preferably washed off. In particular, for forming the core element 70 but also for forming the frame 72 a solder paste or one or several solder balls, respectively, may be used instead of a solder paste or a solder bump.

Either the first substrate 10 or the second substrate 12 or also both substrates may be prepared in the above described way. If the solder is only provided for one of the substrates 10, 12, the other one of the substrates 10, 12 is preferably provided with a fluxing agent at the locations to be soldered. In the following, both substrates are arranged on top of each other stack-shaped. By heating up to a temperature above the melting temperature of the solder the same is remelted again, wherein it wets the first conductive trace 22 and the second conductive trace 24 as well as the third conductive trace 32 and the fourth conductive trace 34 and forms the structures illustrated in FIG. 1 and 2 and 3, respectively.

Instead of the solder, the core element 70 and/or the frame 72 may also be formed from other materials, for example from electrically conductive adhesives or plastics or from metal, in particular from stamped or otherwise preprocessed metal parts. Independent of the material and the manufacturing process, the frame 72 and/or the core element may either be generated directly on one of the substrates 10, 12 or first on an auxiliary substrate, for example on a plastics or metal foil, in order to be then transferred to one of the substrates 10, 12.

A metallic frame and/or a metallic core element not consisting of a solder may be clamped between the first conductive trace 22 and the third conductive trace 32 or between the second conductive trace 24 and the fourth conductive trace 34, respectively, or be connected to the same in a mechanically and electrically conductive way by thin conductive adhesive layers or thin solder layers.

Preferably, after the formation of the core element 70 and the frame 72 the connecting body 80 is formed outside the frame 72 between the substrates 10, 12 which mechanically combines the substrates 10, 12. The connecting body 80 absorbs mechanical stresses between the substrates 10, 12, which may for example come from different coefficients of thermal expansion, and in this way reduces the mechanical load on the core element 70 and the frame 72. Thereby again, the reliability of the substrate stack is increased. The connecting body 80 preferably comprises a polymer, for example, an epoxy or epoxy resin, respectively, filled with a ceramic filler material. The connecting body 80 is formed by directly dispensing the unhardened epoxy on the slot between the substrates 10, 12 and consequently heating it up. At that time, the epoxy is liquefied and its viscosity decreases, respectively, and it is drawn into the slot between the substrates 10, 12 by capillary forces. There it is consequently hardened.

The closed ring structure seen in FIG. 2 of the frame 72 thereby prevents that the epoxy may penetrate the gap 78 between the frame 72 and the core element 70. This is an important advantage as the epoxy comprises unfavorable dielectric and attenuation properties and is therefore undesirable within the gap 78. The closed ring structure of the frame 72 thereby on the one hand facilitates the advantageous formation of the connecting body 80 without on the other hand influencing the impedance and the attenuation properties of the signal path formed by the core element 70 and the frame 72 between the substrates 10, 12.

Simultaneously, according to the present invention an especially short connecting height and an especially short distance of the two substrates 10, 12 from each other, respectively, is realizable, also when the ceramic material of the second substrate 12 comprises an especially low coefficient of thermal expansion and thereby strongly differs from the conductor plate 10. Connecting heights between 50 μm and 200 μm or also below 50 μm are obtainable. Those short connecting heights are advantageous and desirable regarding a low-reflection signal transmission between the substrates 10, 12.

If the frame 72 does not comprise a closed ring structure, as it is illustrated in FIG. 2, but one or several openings 82, these openings are preferably so small that they do not influence the electromagnetic shielding on the one hand and do not facilitate a penetration of the epoxy into the gap 78 between the core element 70 and the frame 72 on the other hand. For this purpose, it is usually sufficient to implement the opening 82 narrow and long and in particular smaller than the distance between the substrates 10, 12. The opening 82 may extend in a vertical direction from the first surface 20 of the first substrate 10 to the first surface 30 of the second substrate 12 or may abut only to the first surface 20 of the first substrate 10 or only to the first surface 30 of the second substrate 12. The concrete dimensioning of the opening 82 thereby depends on the capillary forces and the size of the surface tension of the epoxy, respectively, of the viscosity of the epoxy and of the period of time during which the epoxy is liquid.

Deviating from the illustration in FIG. 2 and 3, the frame 72 may comprise an elliptical, an oval, a rectangular or any other shape instead of an annular ring shape. In the interior of the frame 72 several core elements 70 may be arranged which are for example provided for a parallel and simultaneous transmission of several electrical signals Each individual core element may thereby, also deviating from the illustrations in FIG. 2 and 3, comprise a rectangular or any other section instead of the circular section. The frame 72 may comprise one or several openings 82, as mentioned above, wherein, however, the sum of the opening widths of the openings is preferably not more than half of the perimeter of the frame 72.

According to an advantageous implementation of the present invention the frame 72 and the core element 70 are arranged at an edge of the first substrate 10 and/or at an edge of the second substrate 12, wherein the frame 72 approximately comprises the shape of a horseshoe, wherein its opening is directed to the edge or to the edges of the substrates 10, 12, respectively. This implementation facilitates a very good shielding of the signal path formed by the core 70 against all electromagnetic interferences originating from the substrates 10, 12 and a mechanically stable connection of the two substrates to each other. At the same time, this implementation facilitates a generous opening of the frame 72, which facilitates an easy escape of liquid or gaseous substances (for example flux components during soldering) occurring during the manufacturing process within the gap 78.

Further, the shapes of the core element 70 and/or the frame 72 on the first surface 20 of the first substrate 10 may deviate from those on the first surface 30 of the second substrate 12. For example, the first conductive trace 22 may comprise a different interior diameter than the third conductive trace 32 and/or the second conductive trace 24 may comprise a different diameter or a different shape than the fourth conductive trace 34. These different shapes may originate from different manufacturing processes of the first substrate 10 and the second substrate 12. Different geometries of the conductive traces at the two substrates 10, 12 may however also be provided in order to generate the same impedance in both substrates with different dielectric constants and different relative permittivities, respectively.

What is claimed is:

1. A substrate stack, comprising:
a first substrate;
a second substrate arranged opposite the first substrate;
a frame connecting the first substrate and the second substrate to each other, wherein the frame is a closed frame or comprises one or several openings, which occupy less than half of the perimeter of the frame; and
a core element, also connecting the first substrate and the second substrate to each other and arranged within the frame.

2. The substrate stack according to claim 1, wherein the frame and the core element are electrically conductive and spaced apart.

3. The substrate stack according to claim 2, wherein the area in the interior of the frame and the area of the core element determine a predefined wave resistance.

4. The substrate stack according to claim 1, wherein the frame comprises exactly one opening which occupies a predetermined part of the perimeter of the frame.

5. The substrate stack according to claim 1, wherein the one or several openings spaced apart from each other are implemented so that a flowable material introducible between the first substrate and the second substrate does not penetrate the frame.

6. The substrate stack according to claim 1, further comprising a connecting body arranged within a gap between the first substrate and the second substrate mechanically connecting the first substrate and the second substrate to each other.

7. The substrate stack according to claim 6, wherein the connecting body is exclusively arranged outside the frame.

8. The substrate stack according to claim 1, wherein the first substrate and the second substrate comprise different materials.

9. The substrate stack according to claim 1, wherein the core element forms an electrically conductive connection for transmitting a signal between the first substrate and the second substrate and wherein the frame forms an electromagnetic shielding for the core element.

10. The substrate stack according to claim 1, wherein the core element and the frame are arranged at an edge of the first substrate and/or at an edge of the second substrate, wherein one of the one or several openings is arranged at the edge of the first substrate or at the edge of the second substrate, respectively.

11. A method for producing a substrate stack, comprising:
providing a first substrate;
providing a second substrate;
depositing a frame onto the first substrate, wherein the frame is a closed frame or comprises one or several openings, wherein the one or several openings occupy less than half of the perimeter of the frame;
depositing the core element onto the first substrate or onto the second substrate; and
depositing the frame onto the second substrate in order to connect the first substrate and the second substrate to each other, wherein the core element is arranged in the interior of the frame.

12. The method according to claim 11,
wherein the step of depositing the frame onto the first substrate includes a step of depositing a solder paste onto the first substrate; and
wherein the step of depositing the frame onto the second substrate includes a step of remelting the solder paste, wherein the solder paste wets the second substrate.

13. The method according to claim 12, further comprising a step of depositing a further solder paste or a fluxing agent onto the second substrate.

14. The method according to claim 11, further comprising:
flowing of a connecting material into a gap between the first substrate and the second substrate; and
hardening of the connecting material within the gap, in order to provide a mechanical connection between the first substrate and the second substrate.

15. The method according to claim 14, wherein at the step of flowing, the connecting material does not penetrate the frame.

16. A substrate, comprising:
a frame which is attached on the substrate and is closed or comprises one or several openings, wherein the one or several openings occupy less than half of the perimeter of the frame; and
a core element arranged on the substrate within the frame;
wherein the frame and the core element are provided for connecting the substrate to a further substrate.

17. The substrate according to claim 16, wherein the one or several openings are implemented so that after connecting the substrate to a further substrate a flowable medium inserted between the substrate and the further substrate does not penetrate the frame.

18. Substrate according to claim 16, wherein the core element and the frame are arranged at an edge of the substrate, wherein one of the one or several openings is arranged at the edge of the first substrate or at the edge of the second substrate, respectively.

19. An auxiliary substrate, comprising:
a frame which is arranged on the auxiliary substrate and which is closed or comprises one or several openings, wherein the one or several openings occupy less than half of the perimeter of the frame; and
a core element which is arranged on the auxiliary substrate within the frame;
wherein the frame and the core element are provided to be transmitted to a first substrate from the auxiliary substrate in order to connect the first substrate to a second substrate.
